(19) United States
(12) Patent Application Publication
(10) Pub. No.: US 2025/0107295 A1
(43) Pub. Date: Mar. 27, 2025

(54) STRETCHABLE DISPLAY DEVICE

(71) Applicant: ELECTRONICS AND TELECOMMUNICATIONS RESEARCH INSTITUTE, Daejeon (KR)

(72) Inventors: Himchan OH, Daejeon (KR); Jae Bon KOO, Daejeon (KR); Chan Woo PARK, Daejeon (KR); Ji-Young OH, Daejeon (KR)

(21) Appl. No.: 18/767,643

(22) Filed: Jul. 9, 2024

(30) Foreign Application Priority Data
Sep. 27, 2023 (KR) 10-2023-0130382
Apr. 29, 2024 (KR) 10-2024-0056599

(51) Int. Cl. H01L 33/60; H01L 25/16

(52) U.S. Cl. CPC H10H 20/856; H01L 25/167

(57) ABSTRACT

The present disclosure provides a stretchable display device. The stretchable display device according to an embodiment of the inventive concept includes a lower substrate, a reflective layer on the lower substrate, pixels provided on the reflective layer to generate light, and a diffusion layer which is provided between the pixels and the reflective layer and diffuses the light onto the reflective layer.

### CROSS-REFERENCE TO RELATED APPLICATIONS

This U.S. non-provisional patent application claims priority under 35 U.S.C. § 119 of Korean Patent Application Nos. 10-2023-0130382, filed on Sep. 27, 2023, and 10-2024-0056599, filed on Apr. 29, 2024, the entire contents of which are hereby incorporated by reference.

### BACKGROUND

The present disclosure herein relates to a display device, and more particularly, to a stretchable display device.

In general, stretchable display devices are display devices which vary and use areas of displays as necessary. Recently, the stretchable display devices which are easily portable and in which display areas are variable are developed.

### SUMMARY

The present disclosure provides a stretchable display device capable of reducing or minimizing a decrease in resolution when being stretched.

An embodiment of the inventive concept provides a stretchable display device. The stretchable display device according to an embodiment of the inventive concept includes a lower substrate, a reflective layer on the lower substrate, pixels which are provided on the reflective layer and generate light, and a diffusion layer which is provided between the pixels and the reflective layer, and diffuses the light onto the reflective layer.

In an embodiment, each of the pixels may include an upper substrate, and first to third light emitting diodes on the upper substrate.

In an embodiment, the first to third light emitting diodes may be arranged in a ring shape.

In an embodiment, the diffusion layer may include a boundary diffusion layer provided outside the first to third light emitting diodes, an inner diffusion layer provided inside the boundary diffusion layer, and a lens diffusion layer provided between the inner diffusion layer and the boundary diffusion layer, and provided below each of the first to third light emitting diodes.

In an embodiment, the lens diffusion layer may include first to third sector diffusion layers aligned below the first to third light emitting diodes, respectively.

In an embodiment, the boundary diffusion layer may have a mesh shape.

In an embodiment, the inner diffusion layer may have a circular shape.

In an embodiment, the diffusion layer may have a semicircular or semilunar shape.

In an embodiment, the stretchable display device may further include an insulation layer between the diffusion layer and the reflective layer.

In an embodiment, the diffusion layer may have a plurality of diffusion particles.

In an embodiment of the inventive concept, a stretchable display device includes a substrate, a reflective layer on the substrate, an insulation layer on the reflective layer, pixels which are provided on the insulation layer and generate light, and a diffusion layer which is provided in the insulation layer and diffuses the light onto the reflective layer.

In an embodiment, the substrate may include a stretchable substrate.

In an embodiment, the diffusion layer may include a boundary diffusion layer provided outside the pixels.

In an embodiment, the diffusion layer may further include an inner diffusion layer inside the boundary diffusion layer.

In an embodiment, the diffusion layer may further include a lens diffusion layer provided between the boundary diffusion layer and the inner diffusion layer.

In an embodiment of the inventive concept, a stretchable display device includes a substrate, a reflective layer on the substrate, pixels provided on the reflective layer, and a diffusion layer provided between the pixels and the reflective layer. Here, the diffusion layer may include first to third sector diffusion layers.

In an embodiment, the first to third sector diffusion layers may be arranged in a ring shape.

In an embodiment, each of the pixels may include first to third light emitting diodes on the first to third sector diffusion layers.

In an embodiment, the diffusion layer may further include an inner diffusion layer between the first to third sector diffusion layers.

In an embodiment, the diffusion layer may further include a boundary diffusion layer outside the lens diffusion layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view illustrating one example of a stretchable display device according to an embodiment of the inventive concept;

FIG. 2 illustrates a cross-sectional view taken along line I-I′ in FIG. 1;

FIG. 3 is a plan view illustrating one example of lower lines in FIG. 2;

FIG. 4 is a circuit diagram illustrating one example of lower lines and pixels in FIGS. 2 and 3;

FIG. 5 is a cross-sectional view illustrating one example of a diffusion layer in FIG. 2;

FIG. 6 is a cross-sectional view illustrating one example of a diffusion layer in FIG. 2;

FIGS. 7A and 7B are cross-sectional views illustrating one example of the diffusion layer in FIG. 6;

FIG. 8 is a plan view illustrating one example of a stretchable display device according to an embodiment of the inventive concept;

FIGS. 9 and 10 illustrate cross-sectional views taken along lines II-II′ and III-III′ in FIG. 8, respectively;

FIG. 11 is a plan view illustrating one example of a stretchable display device according to an embodiment of the inventive concept;

FIG. 12 is a plan view illustrating one example of a stretchable display device according to an embodiment of the inventive concept; and

FIG. 13 is a plan view illustrating one example of a pixel, a scan line, and data lines in FIG. 12.

### DETAILED DESCRIPTION

Hereinafter, embodiments of the inventive concept will be described in detail with reference to the accompanying drawings. Advantages and features of the present invention, and implementation methods thereof will be clarified through following embodiments described in detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

The terminology used herein is for the purpose of describing embodiments only and is not intended to be limiting of the invention. As used herein, the singular forms are intended to include the plural forms as well, unless the context clearly indicates otherwise. It will be further understood that the terms “comprises” and/or “comprising”, when used in this specification, specify the presence of stated components, operations, and/or elements, but do not preclude the presence or addition of one or more other components, operations, and/or elements. Since preferred embodiments are provided below, the order of the reference numerals given in the description is not necessarily limited thereto.

Additionally, the embodiments herein will be described with reference to cross-sectional views and/or plan views as ideal exemplary views of the present invention. In the drawings, the thicknesses of layers and regions are exaggerated for effective description of the technical contents. Accordingly, shapes of the exemplary views may be modified according to manufacturing techniques and/or allowable errors. Therefore, the embodiments of the inventive concept are not limited to the specific shape illustrated in the views, but may include other shapes created according to manufacturing processes.

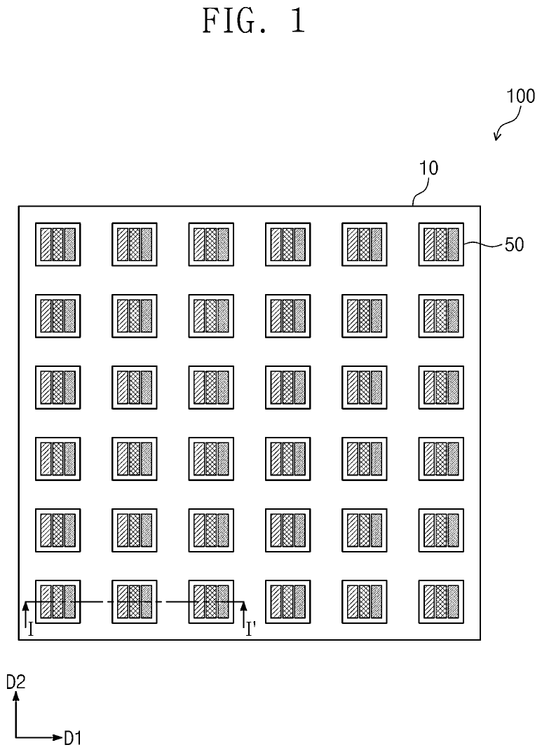

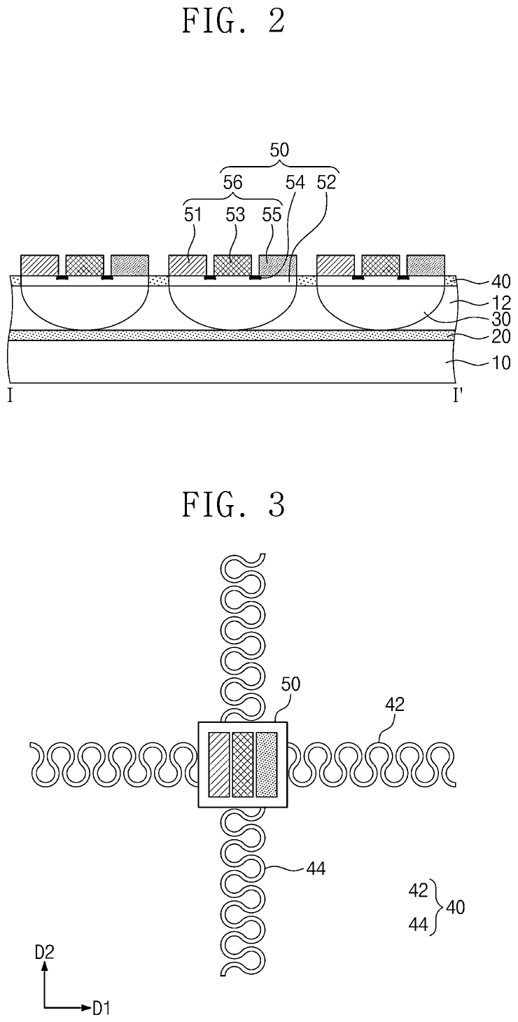

FIG. 1 illustrates one example of a stretchable display device 100 according to an embodiment of the inventive concept. FIG. 2 illustrates a view taken along line I-I′ in FIG. 1.

Referring to FIGS. 1 and 2, the stretchable display device 100 according to an embodiment of the inventive concept may include a light emitting display (LED). Alternatively, the stretchable display device 100 may include an organic light emitting display (OLED), and an embodiment of the inventive concept is not limited thereto. According to an embodiment, the stretchable display device 100 may include a lower substrate 10, a reflective layer 20, a diffusion layer 30, lower lines 40, and pixels 50.

The lower substrate 10 may include an elastic substrate or a flexible substrate. For example, the lower substrate 10 may include polydimethylsiloxane (PDMS). Alternatively, the lower substrate 10 may include polyimide, and an embodiment of the inventive concept is not limited thereto.

The reflective layer 20 may be provided on the lower substrate 10. The reflective layer 20 may reflect light. For example, the reflective layer 20 may include a metal layer made of silver (Ag) or aluminum (Al).

An insulation layer 12 may be provided on the reflective layer 20. The insulation layer 12 may include a transparent polymer of PDMS or polyimide. Alternatively, the insulation layer 12 may include a silicon oxide or a silicon nitride, and an embodiment of the inventive concept is not limited thereto.

The diffusion layer 30 may be provided on the insulation layer 12. The diffusion layer 30 may be provided in the insulation layer 12, and an embodiment of the inventive concept is not limited thereto. According to an embodiment, the diffusion layer 30 may include a lens diffusion layer that is convex downward. For example, the diffusion layer 30 may have a semicircular or semilunar shape on a vertical view.

Although not illustrated, the diffusion layer 30 may have a circular or rectangular shape on a plan view. The diffusion layer 30 may diffuse light of the pixels 50. The diffusion layer 30 may include a silicon oxide, a silicon nitride, a silicon oxynitride, or quartz. The diffusion layer 30 may include a transparent or semi-transparent polymer, and an embodiment of the inventive concept is not limited thereto.

The lower lines 40 may be provided on the insulation layer 12 between the diffusion layers 30. The lower lines 40 may connect the pixels 50 to each other. The lower lines 40 may provide electrical signals and power voltages to the pixels 50. For example, the lower lines 40 may include a metal such as gold (Au), silver (Ag), copper (Cu), aluminum (Al), tungsten (W), molybdenum (Mo), nickel (Ni), titanium (Ti), or tantalum (Ta). Alternatively, the lower lines 40 may include an indium tin oxide (ITO), and an embodiment of the inventive concept is not limited thereto.

FIG. 3 illustrates one example of the lower lines 40 in FIG. 2.

Referring to FIG. 3, the lower lines 40 may each have a corrugated shape or a meandering shape on a plan view. When the lower substrate 10 in FIG. 2 is stretched, the lower lines 40 may be elongated or expanded in a first direction D1 and a second direction D2. When the lower substrate 10 is contracted, the lower lines 40 may be shortened or contracted in the first direction D1 and the second direction D2.

According to an embodiment, the lower lines 40 may include a scan line 42 and a data line 44. The scan line 42 may extend in the first direction D1. The scan line 42 may be a gate line. The data line 44 may extend in the second direction D2. The data line 44 may be a source line or a color signal line.

Referring to FIGS. 1 and 2 again, the pixels 50 may be provided on the diffusion layer 30. The pixels 50 may be connected between the lower lines 40. The pixels 50 may generate light.

According to an embodiment, each of the pixels 50 may include an upper substrate 52, upper lines 54, and light emitting diodes 56.

The upper substrate 52 may be selectively provided on the diffusion layer 30. The upper substrate 52 may have stretchability or elasticity lower than stretchability or elasticity of the lower substrate 10. The upper substrate 52 may be transparent. For example, the upper substrate 52 may include polyimide.

The upper lines 54 may be provided on the upper substrate 52. The upper lines 54 may connect the light emitting diodes 56 on the upper substrate 52 to each other. The upper lines 54 may include an opaque metal such as gold (Au), silver (Ag), copper (Cu), aluminum (Al), tungsten (W), molybdenum (Mo), nickel (Ni), titanium (Ti), or tantalum (Ta). Alternatively, the upper lines 54 may include an indium tin oxide (ITO) or a transparent metal, and an embodiment of the inventive concept is not limited thereto.

The light emitting diodes 56 may be provided on the upper substrate 52. The light emitting diodes 56 may generate light having a red color, a blue color, and a green color. Although not illustrated, each of the light emitting diodes 56 may include a lower transparent electrode, a light emitting layer on the lower transparent electrode, and an upper transparent electrode on the light emitting layer on a vertical view. The lower transparent electrode may include ITO. The light emitting layer may include a Group III-V semiconductor layer or an organic polymer. The light emitting layer may generate the light having the red color, the blue color, and the green color by bias current between the lower transparent electrode and the upper transparent electrode. The upper transparent electrode may be provided on the light emitting layer. The upper transparent electrode may include ITO.

According to an embodiment, each of the light emitting diodes 56 may include a first light emitting diode 51, a second light emitting diode 53, and a third light emitting diode 55 on a plan view. The first light emitting diode 51 may be provided on one side of the diffusion layer 30. The first light emitting diode 51 may generate red light. The second light emitting diode 53 may be provided on a central portion of the diffusion layer 30. The second light emitting diode 53 may generate green light. The third light emitting diode 55 may be provided on the other side of the diffusion layer 30. The third light emitting diode 55 may generate blue light.

The reflective layer 20 may reflect the red light, the green light, and the blue light. When the lower substrate 10 is stretched, the diffusion layer 30 may diffuse the red light, the green light, and the blue light onto the reflective layer 20. The diffused red light, green light, and blue light may be reflected by the reflective layer 20.

Therefore, the stretchable display device 100 according to an embodiment of the inventive concept may use the diffusion layer 30 between the lower substrate 10 and the pixels 50 to reduce or minimize a decrease in resolution when the lower substrate 10 is stretched.

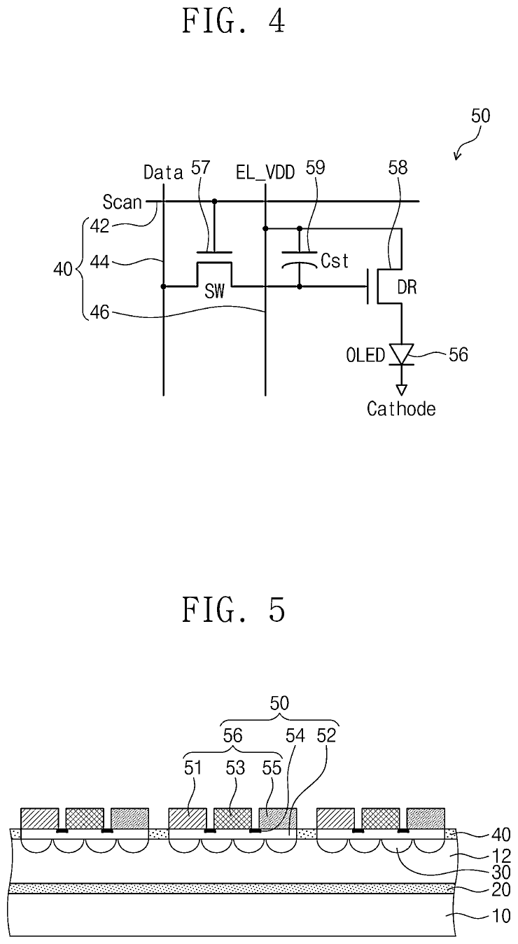

FIG. 4 illustrates one example of the lower lines 40 and the pixels 50 in FIGS. 2 and 3.

Referring to FIG. 4, the lower lines 40 may further include a power line 46, and the pixels 50 may each further include a first thin film transistor 57, a second thin film transistor 58, and a first capacitor 59.

The power line 46 may be parallel to the data line 44. The power line 46 may supply a power voltage to the light emitting diode 56.

The first thin film transistor 57 may be connected to the scan line 42 and the data line 44. The first thin film transistor 57 may be a switching transistor. The first thin film transistor 57 may control a turn-on signal of the power voltage. The first thin film transistor 57 may have a gate electrode connected to the scan line 42, and a source electrode connected to the data line 44. The first thin film transistor 57 may have a drain electrode connected to a gate electrode of the second thin film transistor 58.

The second thin film transistor 58 may be connected to the power line 46, the first thin film transistor 57, and the light emitting diode 56. The second thin film transistor 58 may control the power voltage. The second thin film transistor 58 may have a source electrode connected to the power line 46, the gate electrode connected to the first thin film transistor 57, and a drain electrode connected to the light emitting diode 56.

The first capacitor 59 may be provided between a gate of the second thin film transistor 58 and the power line 46. One end of the first capacitor 59 may be connected between a drain of the first thin film transistor 57 and the gate of the second thin film transistor 58, and the other end of the first capacitor 59 may be connected between the power line 46 and a source of the second thin film transistor 58. The first capacitor 59 may adjust emission time of the light emitting diodes 56.

FIG. 5 illustrates one example of the diffusion layer 30 in FIG. 2.

Referring to FIG. 5, the diffusion layer 30 may have a plurality of convex portions on a lower side of an upper substrate 52 of pixels 50. The plurality of convex portions may be provided below a first light emitting diode 51, a second light emitting diode 53, and a third light emitting diode 55, respectively.

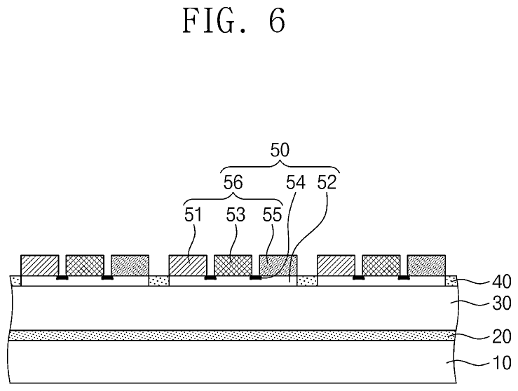

FIG. 6 illustrates one example of the diffusion layer 30 in FIG. 2.

Referring to FIG. 6, the diffusion layer 30 may be provided between a reflective layer 20 and pixels 50 without the insulation layer 12 in FIG. 2. The diffusion layer 30 may be provided between the reflective layer 20 and lower lines 40. The diffusion layer 30 may be flat.

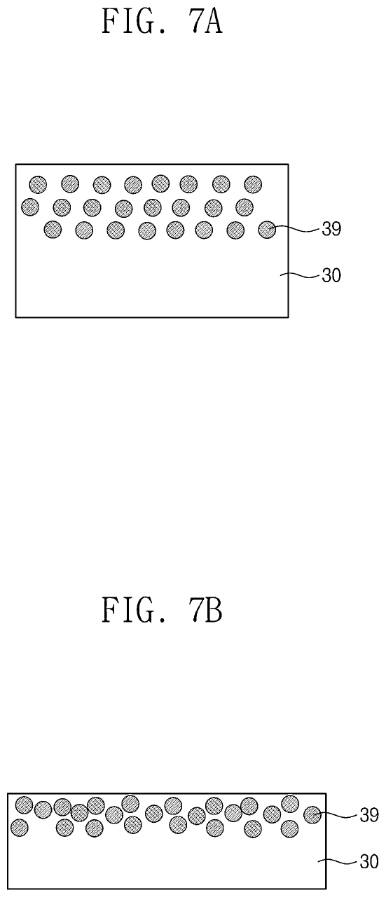

FIGS. 7A and 7B each illustrate one example of the diffusion layer 30 in FIG. 6.

Referring to FIGS. 7A and 7B, the diffusion layer 30 may have a plurality of diffusion particles 39. The diffusion particles 39 may be provided in the diffusion layer 30. When the diffusion layer 30 is stretched in the first direction D1 or the second direction D2, a distance between the diffusion particles 39 may be decreased. The diffusion particles 39 may each have a refractive index higher than a refractive index of the diffusion layer 30. For example, the diffusion particles 39 may include a transparent polymer.

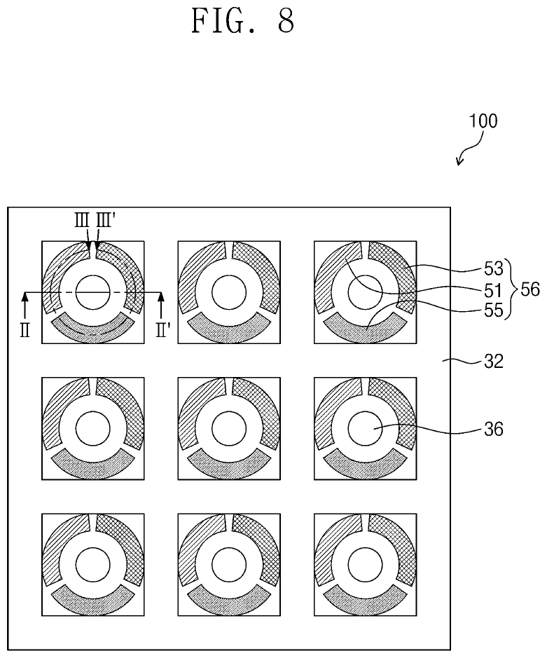

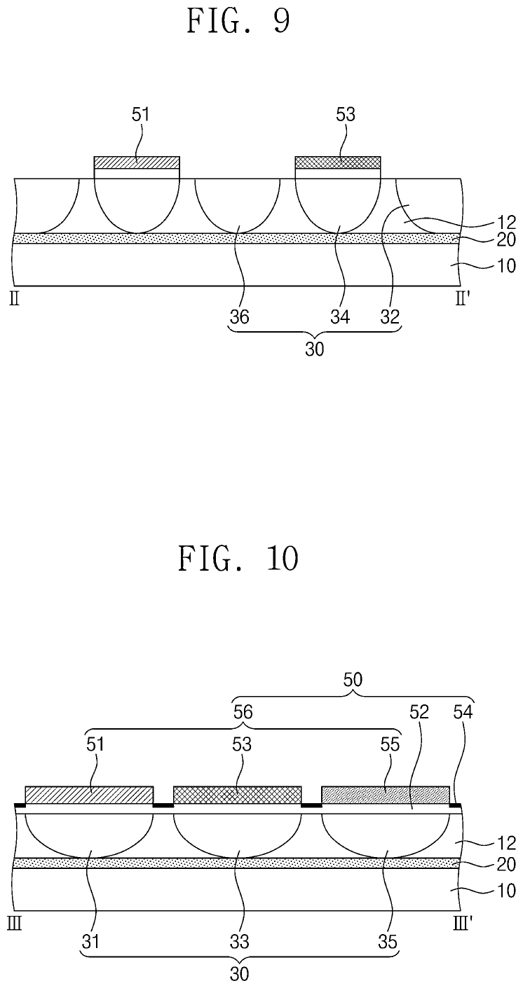

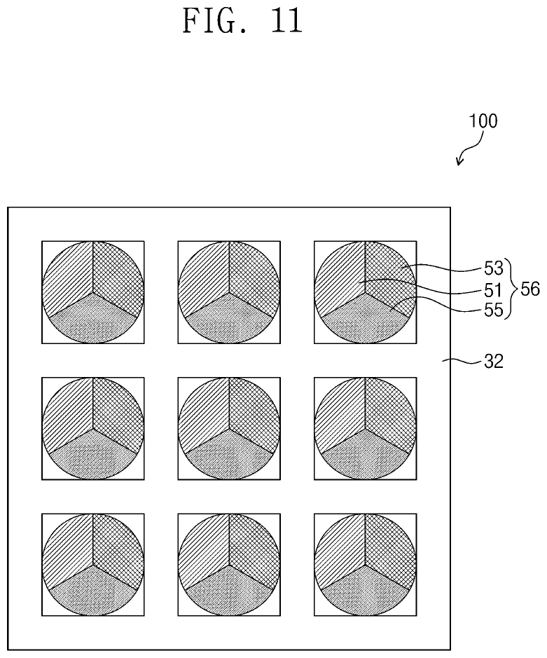

FIG. 8 illustrates one example of a stretchable display device 100 according to an embodiment of the inventive concept. FIGS. 9 and 10 illustrate views taken along lines II-II′ and III-III′ in FIG. 8, respectively.

Referring to FIGS. 8 to 10, light emitting diodes 56 of the stretchable display device 100 according to an embodiment of the inventive concept may be arranged in a ring shape. A diffusion layer 30 may be provided outside and inside the light emitting diodes 56 on a plan view. The diffusion layer 30 may overlap the light emitting diodes 56.

Referring to FIG. 9, the diffusion layer 30 may include a boundary diffusion layer 32, a lens diffusion layer 34, and an inner diffusion layer 36.

The boundary diffusion layer 32 may be provided outside the light emitting diodes 56. The boundary diffusion layer 32 may surround peripheries of pixels 50. That is, the boundary diffusion layer 32 may be provided at boundaries of the pixels 50. The boundary diffusion layer 32 may have a mesh shape on a plan view as in FIG. 8. The boundary diffusion layer 32 may diffuse light outside the light emitting diodes 56.

The inner diffusion layer 36 may be provided between the light emitting diodes 56. The inner diffusion layer 36 may be provided inside the light emitting diodes 56. The inner diffusion layer 36 may have a circular shape on a plan view. The inner diffusion layer 36 may diffuse light between the light emitting diodes 56.

The lens diffusion layer 34 may be provided between the inner diffusion layer 36 and the boundary diffusion layer 32. The lens diffusion layer 34 may be provided below the light emitting diodes 56. The lens diffusion layer 34 may diffuse light below the light emitting diodes 56.

Referring to FIG. 10, the lens diffusion layer 34 may include a first sector diffusion layer 31, a second sector diffusion layer 33, and a third sector diffusion layer 35.

The first sector diffusion layer 31 may be aligned below a first light emitting diode 51. The first sector diffusion layer 31 may diffuse red light of the first light emitting diode 51.

The second sector diffusion layer 33 may be provided at one side of the first sector diffusion layer 31. The second sector diffusion layer 33 may be aligned below a second light emitting diode 53. The second sector diffusion layer 33 may diffuse green light of the second light emitting diode 53.

The third sector diffusion layer 35 may be provided at one side of the second sector diffusion layer 33. The third sector diffusion layer 35 may be aligned below a third light emitting diode 55. The third sector diffusion layer 35 may diffuse blue light of the third light emitting diode 55.

FIG. 11 illustrates one example of a stretchable display device 100 according to an embodiment of the inventive concept.

Referring to FIG. 11, light emitting diodes 56 of the stretchable display device 100 according to an embodiment of the inventive concept may be arranged in a circular shape. Each of a first light emitting diode 51, a second light emitting diode 53, and a third light emitting diode 55 may have a fan shape. The first light emitting diode 51, the second light emitting diode 53, and the third light emitting diode 55 may be arranged in sequence in an azimuthal direction.

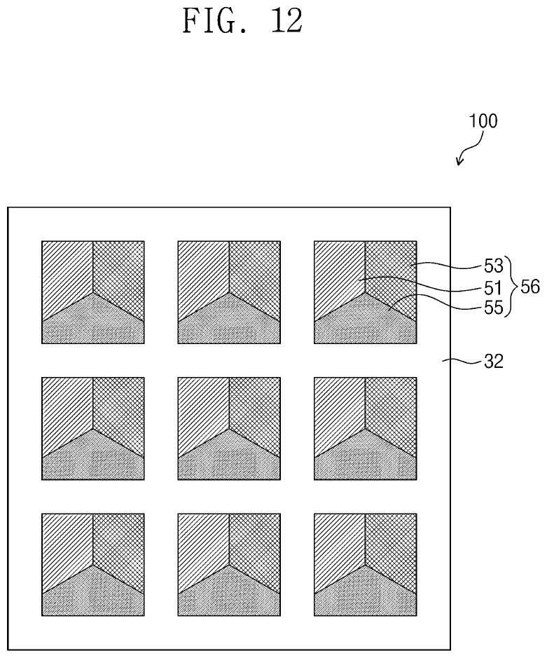

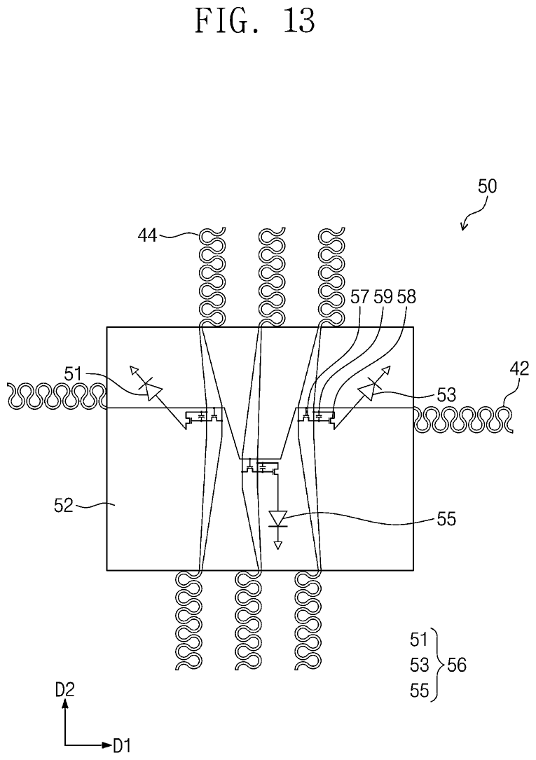

FIG. 12 illustrates one example of a stretchable display device 100 according to an embodiment of the inventive concept.

Referring to FIG. 12, light emitting diodes 56 of the stretchable display device 100 according to an embodiment of the inventive concept may be arranged in a rectangular shape. A first light emitting diode 51, a second light emitting diode 53, and a third light emitting diode 55 may be arranged in sequence in an azimuthal direction. The first light emitting diode 51 and the second light emitting diode 53 may each have a trapezoidal shape. The third light emitting diode 55 may have a pentagonal shape.

FIG. 13 illustrates one example of a pixel 50, a scan line 42, and data lines 44 in FIG. 12.

Referring to FIG. 13, an upper substrate 52 of the pixel 50 may be connected to one scan line 42 in the first direction D1, and connected to three data lines 44 in the second direction D2. The scan line 42 and the data lines 44 may each have a meandering shape on a plan view. The scan line 42 and the data lines 442 may be stretched in the first direction D1 and the second direction D2, respectively.

As described above, the stretchable display device according to the embodiment of the inventive concept may use the diffusion layer between the lower substrate and the pixels to reduce or minimize the decrease in resolution when the lower substrate is stretched.

Although the embodiments of the present invention have been described, it is understood that the present invention should not be limited to these embodiments but various changes and modifications can be made by one ordinary skilled in the art within the spirit and scope of the present invention as hereinafter claimed. Therefore, it should be understood that the embodiments described above are intended to be illustrative and not for purposes of limitation in all aspects.

What is claimed is:

1. A stretchable display device comprising:
a lower substrate;
a reflective layer on the lower substrate;
pixels provided on the reflective layer and configured to generate light; and
a diffusion layer provided between the pixels and the reflective layer, and configured to diffuse the light onto the reflective layer.

2. The stretchable display device of claim 1, wherein each of the pixels comprises:
an upper substrate; and
first to third light emitting diodes on the upper substrate.

3. The stretchable display device of claim 2, wherein the first to third light emitting diodes are arranged in a ring shape.

4. The stretchable display device of claim 3, wherein the diffusion layer comprises:
a boundary diffusion layer provided outside the first to third light emitting diodes;
an inner diffusion layer provided inside the boundary diffusion layer; and
a lens diffusion layer provided between the inner diffusion layer and the boundary diffusion layer, and provided below each of the first to third light emitting diodes.

5. The stretchable display device of claim 4, wherein the lens diffusion layer comprises first to third sector diffusion layers aligned below the first to third light emitting diodes, respectively.

6. The stretchable display device of claim 4, wherein the boundary diffusion layer has a mesh shape.

7. The stretchable display device of claim 4, wherein the inner diffusion layer has a circular shape.

8. The stretchable display device of claim 1, wherein the diffusion layer has a semicircular or semilunar shape.

9. The stretchable display device of claim 1, further comprising an insulation layer between the diffusion layer and the reflective layer.

10. The stretchable display device of claim 1, wherein the diffusion layer has a plurality of diffusion particles.

11. A stretchable display device comprising:
a substrate;
a reflective layer on the substrate;
an insulation layer on the reflective layer:
pixels provided on the insulation layer and configured to generate light; and
a diffusion layer provided in the insulation layer and configured to diffuse the light onto the reflective layer.

12. The stretchable display device of claim 11, wherein the substrate comprises a stretchable substrate.

13. The stretchable display device of claim 11, wherein the diffusion layer comprises a boundary diffusion layer provided outside the pixels.

14. The stretchable display device of claim 13, wherein the diffusion layer further comprises an inner diffusion layer inside the boundary diffusion layer.

15. The stretchable display device of claim 14, wherein the diffusion layer further comprises a lens diffusion layer provided between the boundary diffusion layer and the inner diffusion layer.

16. A stretchable display device comprising:
a substrate;
a reflective layer on the substrate;
pixels provided on the reflective layer; and
a diffusion layer provided between the pixels and the reflective layer,
wherein the diffusion layer comprises first to third sector diffusion layers.

17. The stretchable display device of claim 16, wherein the first to third sector diffusion layers are arranged in a ring shape.

18. The stretchable display device of claim 16, wherein each of the pixels comprises first to third light emitting diodes on the first to third sector diffusion layers.

19. The stretchable display device of claim 16, wherein the diffusion layer further comprises an inner diffusion layer between the first to third sector diffusion layers.

20. The stretchable display device of claim 16, wherein the diffusion layer further comprises a boundary diffusion layer outside the lens diffusion layer.
